(19) United States
(12) Patent Application Publication
(10) Pub. No.: US 2012/0205797 A1
(43) Pub. Date: Aug. 16, 2012

(54) BUMP AND SEMICONDUCTOR DEVICE HAVING THE SAME

(75) Inventors: Jin Ho BAE, Icheon-si (KR); Myung Gun PARK, Seoul (KR)

(73) Assignee: HYNIX SEMICONDUCTOR INC., Icheon-si (KR)

(21) Appl. No.: 13/339,123

(22) Filed: Dec. 28, 2011

(30) Foreign Application Priority Data
Feb. 15, 2011 (KR) 10-2011-0013241

(51) Int. Cl. H01L 23/498

(52) U.S. Cl. 257/737; 257/E23.068

(57) ABSTRACT

A bump includes a metal pillar formed over a structural body; and a diffusion barrier member formed to cover at least a portion of a side surface of the metal pillar.

### CROSS-REFERENCE TO RELATED APPLICATIONS

The present application claims priority to Korean patent application number 10-2011-13241 filed on Feb. 15, 2011, which is incorporated herein by reference in its entirety.

### BACKGROUND OF THE INVENTION

The present invention relates generally to a semiconductor package, and more particularly to a bump and a semiconductor device having the same.

A flip chip package employs a bonding process capable of realizing high density packaging. In the flip chip package, projections, such as solder bumps, serving as electrically conductive wires, are formed on the input/output pads of a semiconductor chip to electrically connect the semiconductor chip with a substrate. The flip chip package provides an advantage in that the operating speed of a semiconductor device can be increased.

Also, in the flip chip package, since the positions of the input/output pads may vary on the semiconductor chip as the occasion demands, a circuit design may be simplified, and since resistance by circuit wiring lines decreases, the flip chip package can reduce power consumption and thereby achieve excellent electrical characteristics. Further, because the back side of the semiconductor chip is exposed to an outside, thermal characteristics can be improved, and a small-sized package can be realized, and bonding can be easily conducted due to self-alignment of solders.

However, since the solder bumps are deformed into rounded shapes due to surface tension while conducting reflow process for bonding the solder bumps, it is difficult to realize the solder bumps of 100 μm or more. Moreover, if the solder bumps are applied with a fine pitch, since the solder bumps are deformed into rounded shapes and adjacent solder bumps may adhere to each other, a fine pitch equal to or smaller than 200 μm cannot be realized.

Under this situation, a technology of using metal pillars instead of solder bumps has been proposed in the art. Nevertheless, in the case of using the metal pillars, due to the out diffusion of the metal component of the metal pillars, adjacent metal pillars may be short-circuited or the fuses of a semiconductor chip may be negatively influenced, and these may cause a fuse fail.

### BRIEF SUMMARY OF THE INVENTION

Embodiments of the present invention are directed to a bump suitable for preventing the diffusion of a metal component of a metal pillar and a semiconductor device having the same.

In one embodiment of the present invention, a bump includes: a metal pillar formed over a structural body; and a diffusion barrier member formed to cover side surfaces of the metal pillar.

The metal pillar may include at least any one of copper, nickel, gold and aluminum, and the diffusion barrier member may include at least any one of Ti, TiN, Ta, TaN, TiSiN and WN.

The bump may further include an additional diffusion barrier member formed between the structural body and the metal pillar or may further include a connection metal layer formed on the metal pillar.

In another embodiment of the present invention, a semiconductor device includes: a first structural body having a first surface and a second surface which faces away from the first surface, and formed with a first electrode pad on the first surface; and a bump formed over the first electrode pad, the bump including a metal pillar formed over the first electrode pad; and a diffusion barrier member formed to cover side surfaces of the metal pillar.

The metal pillar may include at least any one of copper, nickel, gold and aluminum, and the diffusion barrier member may include at least any one of Ti, TiN, Ta, TaN, TiSiN and WN.

The bump may further include a connection metal layer formed on the metal pillar.

The semiconductor device may further include a under-bump metal formed between the first structural body and the bump, and the bump may further include an additional diffusion barrier member formed between the first structural body and the metal pillar.

The first structural body may include any one of a semiconductor device and a printed circuit board. Here, the semiconductor device may include any one selected among an image sensor, a memory semiconductor, a system semiconductor, a passive device, an active device and a sensor semiconductor, and the printed circuit board may include any one selected among a module substrate, a package substrate, a flexible substrate and a main board.

The first structural body may include a fuse on the first surface.

The semiconductor device may further include a second structural body having a third surface which faces the first surface of the first structural body and a fourth surface which faces away from the third surface, and formed with a second electrode pad which is electrically connected with the bump, on the third surface. The second structural body may include any one of a semiconductor device and a printed circuit board. Here, the semiconductor device may include any one selected among an image sensor, a memory semiconductor, a system semiconductor, a passive device, an active device and a sensor semiconductor, and the printed circuit board may include any one selected among a module substrate, a package substrate, a flexible substrate and a main board.

### BRIEF DESCRIPTION OF THE DRAWINGS

FIG. 1 is a cross-sectional view illustrating a bump in accordance with an embodiment of the present invention.

FIG. 2 is a cross-sectional view illustrating a bump in accordance with an embodiment of the present invention.

FIG. 3 is a cross-sectional view illustrating a semiconductor device in accordance with an embodiment of the present invention.

FIG. 4 is a cross-sectional view illustrating a semiconductor device in accordance with an embodiment of the present invention.

FIG. 5 is a cross-sectional view illustrating a semiconductor device in accordance with an embodiment of the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

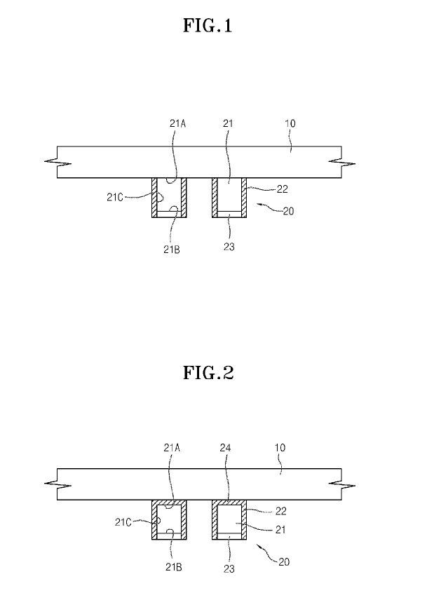

FIG. 1 is a cross-sectional view illustrating a bump in accordance with an embodiment of the present invention.

A bump 20 shown in FIG. 1 may be used as electrical connection means of a structural body 10, for example, such as a semiconductor chip and a printed circuit board.

Referring to FIG. 1, the structural body 10 may include one or more of semiconductor devices such as an image sensor, a memory semiconductor, a system semiconductor, a passive device, an active device and a sensor semiconductor. Alternatively, the structural body 10 may include a printed circuit board such as a module substrate, a package substrate, a flexible substrate and a main board.

The bump 20 is formed on the structural body 10, and includes a metal pillar 21 and a diffusion barrier member 22. Besides, the bump 20 further includes a connection metal layer 23.

The metal pillar 21 is formed on the structural body 10. The metal pillar 21 has the shape of, for example, a circular column or a prism such as a triangular prism. The metal pillar 21 has one end 21A which faces the structural body 10, the other end 21B which faces away from the one end 21A, and side surfaces 21C which connect the one end 21A and the other end 21B with each other. The metal pillar 21 includes one or more of copper, nickel, gold and aluminum.

The diffusion barrier member 22 is formed to cover the side surfaces 21C of the metal pillar 21. The diffusion barrier member 22 serves to prevent the metal component of the metal pillar 21 from diffusing to an outside, and includes one or more of Ti, TiN, Ta, TaN, TiSiN and WN.

The connection metal layer 23 is formed on the other end 21B of the metal pillar 21, and includes one or more of gold (Au), tin (Sn) and a solder. In the present embodiment, the diffusion barrier member 22 is formed not only on the side surfaces 21C of the metal pillar 21 but also on the side surfaces of the connection metal layer 23.

FIG. 2 is a cross-sectional view illustrating a bump in accordance with an embodiment of the present invention.

The bump in accordance with an embodiment of the present invention has the same configuration as the bump according to the embodiment described above with reference to FIG. 1 except an additional diffusion barrier member 24. Therefore, repeated descriptions of the same component parts will be omitted herein, and the same terms and the same reference numerals will be used to refer to the same component parts.

Referring to FIG. 2, the bump 20 includes a metal pillar 21, a diffusion barrier member 22, and an additional diffusion barrier member 24. Besides, the bump 20 further includes a connection metal layer 23.

The additional diffusion barrier member 24 is formed between a structural body 10 and the metal pillar 21. The additional diffusion barrier member 24 is integrally formed with the diffusion barrier member 22, and includes one or more of Ti, TiN, Ta, TaN, TiSiN and WN.

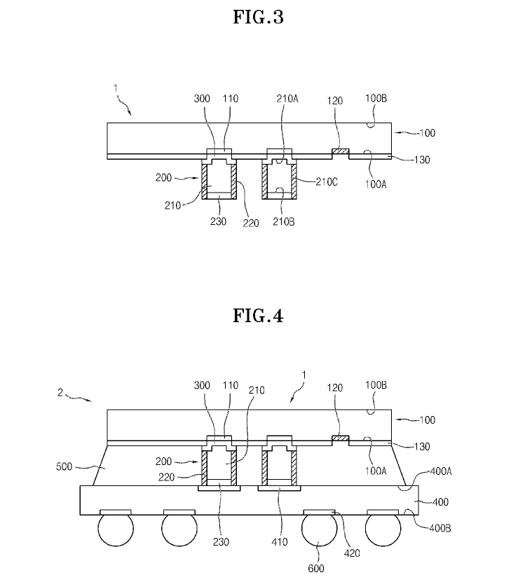

FIG. 3 is a cross-sectional view illustrating a semiconductor device in accordance with an embodiment of the present invention.

Referring to FIG. 3, the semiconductor device 1 in accordance with an embodiment of the present invention includes a first structural body 100, and a bump 200. Besides, the semiconductor device 1 may further include an under-bump metal (UBM) 300.

The first structural body 100 may include a semiconductor device such as an image sensor, a memory semiconductor, a system semiconductor, a passive device, an active device and a sensor semiconductor. Alternatively, the first structural body 100 may include a printed circuit board such as a module substrate, a package substrate, a flexible substrate and a main board.

The first structural body 100 has a first surface 100A and a second surface 100B which faces away from the first surface 100A. The first structural body 100 includes a first electrode pad 110. Besides, the first structural body 100 further includes a fuse 120 and a first dielectric layer pattern 130.

The first electrode pad 110 is formed on the first surface 100A of the first structural body 100. The fuse 120 is formed on the first surface 100A of the first structural body 100 to be separated from the first electrode pad 110. The first dielectric layer pattern 130 is formed on the first surface 100A of the first structural body 100 in such a way as to expose the first electrode pad 110 and the fuse 120.

The bump 200 is formed over the first electrode pad 110 and the adjacent portion of the first dielectric layer pattern 130.

In the present embodiment, the bump 200 may have substantially the same configuration as the bump according to an embodiment described above with reference to FIG. 1.

In detail, the bump 200 includes a metal pillar 210 and a diffusion barrier member 220. Besides, the bump 200 further includes a connection metal layer 230.

The metal pillar 210 is formed over the first electrode pad 110 and the first dielectric layer pattern 130. The metal pillar 210 has the shape of, for example, a circular column or a prism such as a triangular prism. The metal pillar 210 has one end 210A which faces the first structural body 100, the other end 210B which faces away from the one end 210A, and side surfaces 210C which connect the one end 210A and the other end 210B with each other. The metal pillar 210 includes one or more of copper, nickel, gold and aluminum.

The diffusion barrier member 220 is formed to cover the side surfaces 210C of the metal pillar 210. The diffusion barrier member 220 serves to prevent the metal component of the metal pillar 210 from diffusing to an outside, and includes one or more of Ti, TiN, Ta, TaN, TiSiN and WN.

The connection metal layer 230 is formed on the other end 210B of the metal pillar 210, and includes one or more of gold (Au), tin (Sn) and solder. In the present embodiment, the diffusion barrier member 220 is formed not only on the side surfaces 210C of the metal pillar 210 but also on the side surfaces of the connection metal layer 230.

The UBM 300 is formed between the first electrode pad and the dielectric layer pattern 110 and 130 and the bump 200.

Although it was illustrated and explained in the present embodiment that the bump according to the embodiment described above with reference to FIG. 1 is used, it is conceivable that the bump according to the embodiment described above with reference to FIG. 2 may be used.

FIG. 4 is a cross-sectional view illustrating a semiconductor device in accordance with an embodiment of the present invention.

The semiconductor device 2 in accordance with an embodiment of the present invention has a configuration in which the semiconductor device 1 in accordance with the embodiment described above with reference to FIG. 3, is mounted to a second structural body 400 which has a second electrode pad 410, by the medium of a bump 200. Therefore, repeated descriptions of the same component parts will be omitted herein, and the same terms and the same reference numerals will be used to refer to the same component parts.

The second structural body 400 may include one or more of semiconductor devices such as an image sensor, a memory semiconductor, a system semiconductor, a passive device, an active device and a sensor semiconductor. Alternatively, the second structural body 400 may include a printed circuit board such as a module substrate, a package substrate, a flexible substrate and a main board.

The second structural body 400 has a third surface 400A which faces a first structural body 100 and a fourth surface 400B which faces away from the third surface 400A. The second structural body 400 has on the third surface 400A the second electrode pad 410 which is electrically connected with the bump 200, and a third electrode pad 420 on the fourth surface 400B. The second structural body 400 includes therein multi-layered circuit wiring lines (not shown) and conductive vias (not shown) which electrically connect the circuit wiring lines formed at different layers. The second electrode pad 410 and the third electrode pad 420 are electrically connected with each other by the circuit wiring lines and the conductive vias.

In order to improve the reliability of joints, a space in between the first structural body 100 and the second structural body 400 is filled with an underfill component 500, and an external connection terminal 600 such as a solder ball is mounted to the third electrode pad 420 for connection to an external device.

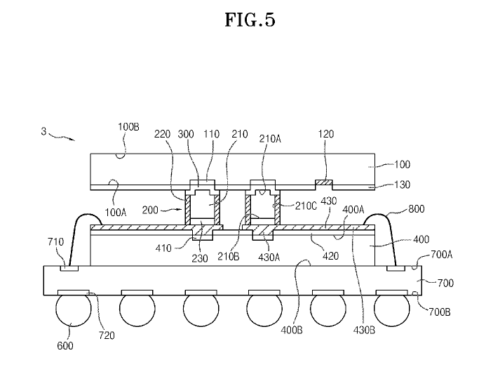

FIG. 5 is a cross-sectional view illustrating a semiconductor device in accordance with an embodiment of the present invention.

Referring to FIG. 5, the semiconductor device 3 in accordance with an embodiment of the present invention includes a first structural body 100, a bump 200, a second structural body 400, a third structural body 700, and a connection member 800. Besides, the semiconductor device 3 further includes a UBM 300 and an external connection terminal 600.

In some embodiments, each of the first structural body 100 and the second structural body 400 may be a semiconductor device such as an image sensor, a memory semiconductor, a system semiconductor, a passive device, an active device and a sensor semiconductor.

The first structural body 100 has a first surface 100A and a second surface 100B which faces away from the first surface 100A. The first structural body 100 includes a first electrode pad 110. Besides, the first structural body 100 further includes a fuse 120 and a first dielectric layer pattern 130.

The first electrode pad 110 is formed on the first surface 100A of the first structural body 100. The fuse 120 is formed on the first surface 100A of the first structural body 100 to be separated from the first electrode pad 110. The first dielectric layer pattern 130 is formed on the first surface 100A of the first structural body 100 in such a way as to expose the first electrode pad 110 and the fuse 120.

The bump 200 is formed over the first electrode pad 110 and the adjacent portion of the first dielectric layer pattern 130.

In the present embodiment, the bump 200 may have substantially the same configuration as the bump according to the embodiment described above with reference to FIG. 1.

In detail, the bump 200 includes a metal pillar 210 and a diffusion barrier member 220. Besides, the bump 200 further includes a connection metal layer 230.

The metal pillar 210 is formed over the first electrode pad 110 and the first dielectric layer pattern 130. The metal pillar 210 has the shape of, for example, a circular column or a prism such as a triangular prism. The metal pillar 210 has one end 210A which faces the first structural body 100, the other end 210B which faces away from the one end 210A, and side surfaces 210C which electrically connect the one end 210A and the other end 210B with each other. The metal pillar 210 includes one or more of copper, nickel, gold and aluminum.

The diffusion barrier member 220 is formed to cover the side surfaces 210C of the metal pillar 210. The diffusion barrier member 220 serves to prevent the metal component of the metal pillar 210 from diffusing to an outside, and includes one or more of Ti, TiN, Ta, TaN, TiSiN and WN.

The connection metal layer 230 is formed on the other end 210B of the metal pillar 210. In the present embodiment, the diffusion barrier member 220 is formed not only on the side surfaces 210C of the metal pillar 210 but also on the side surfaces of the connection metal layer 230.

Although it was illustrated and explained in the present embodiment that the bump according to the embodiment described above with reference to FIG. 1 is used, it is conceivable that the bump according to the embodiment described above with reference to FIG. 2 may be used.

The UBM 300 is formed between the first electrode pad and the dielectric layer pattern 110 and 130 and the bump 200.

The second structural body 400 has a third surface 400A which faces the first structural body 100 and a fourth surface 400B which faces away from the third surface 400A. The second structural body 400 includes on the third surface 400A a second electrode pad 410 and a redistribution line 430. Besides, the second structural body 400 further includes a second dielectric layer pattern 440.

The second electrode pad 410 is formed on the third surface 400A of the second structural body 400. The second dielectric layer pattern 440 is formed on the third surface 400A of the second structural body 400 in such a way as to expose the second electrode pad 410.

The redistribution line 430 is formed on the second electrode pad 410 and the second dielectric layer pattern 440 and redistributes the second electrode pad 410 to an edge of the second structural body 400. One end 430A of the redistribution line 430 is electrically connected to the second electrode pad 410, and the other end 430B of the redistribution line 430 which faces away from the one end 430A is disposed at the edge of the second structural body 400.

The first structural body 100 is mounted over the redistribution line 430 of the second structural body 400 by the medium of the bump 200. That is, the semiconductor device 3 in accordance with an embodiment of the present embodiment has a chip-on-chip structure.

The fourth surface 400B of the second structural body 400 is attached to the third structural body 700.

The third structural body 700 may be, for example, a printed circuit board such as a module substrate, a package substrate, a flexible substrate and a main board.

The third structural body 700 has a fifth surface 700A to which the second structural body 400 is attached and a sixth surface 700B which faces away from the fifth surface 700A.

The third structural body 700 has a fourth electrode pad 710 which is formed outside the second structural body 400 on the fifth surface 700A and a fifth electrode pad 720 which is formed on the sixth surface 700B. The third structural body 700 includes therein multi-layered circuit wiring lines (not shown) and conductive vias (not shown) which connect the circuit wiring lines formed at different layers. The fourth electrode pad 710 and the fifth electrode pad 720 are electrically connected with each other by the circuit wiring lines and the conductive vias.

The connection member 800 electrically connects the other end 430B of the redistribution line 430 with the fourth electrode pad 710 of the third structural body 700, and the external connection terminal 600 is mounted to the fifth electrode 720 of the third structural body 700. The external connection terminal 600 includes a solder ball.

As is apparent from the above descriptions, since the diffusion of a metal component of metal pillars is suppressed by a diffusion barrier member, a probability of the occurrence of a short circuit between metal pillars and the occurrence of a fuse fail may be reduced.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A bump comprising:
a metal pillar formed over a structural body; and
a diffusion barrier member formed to cover at least a portion of a side surface of the metal pillar.

2. The bump according to claim 1, wherein the metal pillar includes one or more of copper, nickel, gold and aluminum.

3. The bump according to claim 1, wherein the diffusion barrier member includes one or more of Ti, TiN, Ta, TaN, TiSiN and WN.

4. The bump according to claim 1, further comprising:
an additional diffusion barrier member formed between the structural body and the metal pillar.

5. The bump according to claim 1, further comprising:
a connection metal layer formed on the metal pillar.

6. A semiconductor device comprising:
a first structural body having a first surface and a second surface which faces away from the first surface, and formed with a first electrode pad on the first surface; and
a bump formed over the first electrode pad,
the bump comprising
a metal pillar formed over the first electrode pad; and
a diffusion barrier member formed to cover at least a portion of a side surface of the metal pillar.

7. The semiconductor device according to claim 6, wherein the metal pillar includes one or more of copper, nickel, gold and aluminum.

8. The semiconductor device according to claim 6, wherein the diffusion barrier member includes one or more of Ti, TiN, Ta, TaN, TiSiN and WN.

9. The semiconductor device according to claim 6, wherein the bump further comprises:
a connection metal layer formed on the metal pillar.

10. The semiconductor device according to claim 6, further comprising:
a under-bump metal formed between the first structural body and the bump.

11. The semiconductor device according to claim 6, wherein the bump further comprises:
an additional diffusion barrier member formed between the first structural body and the metal pillar.

12. The semiconductor device according to claim 6, wherein the first structural body comprises one or more of a semiconductor device and a printed circuit board.

13. The semiconductor device according to claim 12, wherein the semiconductor device comprises one or more of an image sensor, a memory semiconductor, a system semiconductor, a passive device, an active device and a sensor semiconductor.

14. The semiconductor device according to claim 12, wherein the printed circuit board comprises any one selected among a module substrate, a package substrate, a flexible substrate and a main board.

15. The semiconductor device according to claim 6, wherein the first structural body includes a fuse on the first surface.

16. The semiconductor device according to claim 6, further comprising:
a second structural body having a third surface which faces the first surface of the first structural body and a fourth surface which faces away from the third surface, and formed with a second electrode pad which is electrically connected with the bump, on the third surface.

17. The semiconductor device according to claim 16, wherein the second structural body comprises one or more of a semiconductor device and a printed circuit board.

18. The semiconductor device according to claim 17, wherein the semiconductor device comprises one or more of an image sensor, a memory semiconductor, a system semiconductor, a passive device, an active device and a sensor semiconductor.

19. The semiconductor device according to claim 17, wherein the printed circuit board comprises any one selected among a module substrate, a package substrate, a flexible substrate and a main board.
